(19) United States
(12) Patent Application Publication
(10) Pub. No.: US 2001/0048162 A1
(43) Pub. Date: Dec. 6, 2001

(54) Semiconductor device having a structure of a multilayer interconnection unit and manufacturing method thereof

(75) Inventors: Hideyo Haruhana, Tokyo (JP); Hiroyuki Amishiro, Tokyo (JP); Motoshige Igarashi, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/734,204

(22) Filed: Dec. 12, 2000

(30) Foreign Application Priority Data
Jun. 5, 2000 (JP) 2000-167030

(51) Int. Cl. H01L 29/40; H01L 21/44; H01L 23/48

(52) U.S. Cl. 257/751; 257/774; 438/672; 438/675; 438/653

(57) ABSTRACT

A metal wire comprising a metal member and a barrier metal is formed within each of trenches formed in an insulating film placed on a semiconductor substrate. A first metal diffusion preventive film is formed on the insulating film so as to make contact with an upper portion of the barrier metal formed on the sides of the metal. Further, a second metal diffusion preventive film is formed on the first metal diffusion preventive film and the metal wire.

### BACKGROUND OF THE INVENTION

1. Field of the Invention

The present invention generally relates to a semiconductor device and a manufacturing method therefor, and more particularly, to a structure of a multilayer interconnection unit using a damascene technique and a manufacturing method therefor.

2. Description of the Background Art

In a semiconductor device such as an LSI (Large Scale Integrated Circuit) or the like, progress has recently been made in regard to a scale-down of a wire or interconnection and an increase in multilayer interconnection using a damascene technique with high integration of semiconductor elements.

FIGS. 5A to 5F are cross-sectional views for describing a conventional method of manufacturing a semiconductor device.

As shown in FIG. 5A, a wiring-to-wiring insulating film 501 is first formed on an un-illustrated semiconductor substrate by a CVD (Chemical Vapor Deposition) method.

Next, as shown in FIG. 5B, a resist pattern for defining each metal-embedded trench is formed on the surface of the wiring-to-wiring insulating film 501. Afterwards, a metal-embedded trench 501a is formed therein by etching. A barrier metal 502 is formed on the internal surface (corresponding to the bottom and both sides) of the trench 501a and the surface of the wiring-to-wiring insulating film 501. Thereafter, a metal 503 such as Cu or the like is embedded in the trench 501a.

Next, as shown in FIG. 5C, the metal 503 unnecessary for wiring is removed by a CMP (Chemical Mechanical Polishing) method.

Further, the barrier metal 502 placed on the wiring-to-wiring insulating film 501 is eliminated by the CMP method as shown in FIG. 5D.

Finally, a metal diffusion preventive film 504 is formed on the metal-embedded wire 503 and the wiring-to-wiring insulating film 501 by the CVD method as shown in FIG. 5E.

In the conventional method, however, the barrier metal 502 placed on the wiring-to-wiring insulating film 501 is removed by the CMP method. Thereafter, the surfaces of the wiring-to-wiring insulating film 501, the barrier metal 502 and the metal 503 are simultaneously exposed. Since a polishing rate of the barrier metal 502 is faster than polishing rates of the wiring-to-wiring insulating film 501 and the metal 503, the surface of the barrier metal 502 becomes lower than the surfaces of the wiring-to-wiring insulating film 501 and the metal 503.

Thereafter, the metal diffusion preventive film 504 is formed on the exposed surface. As a result, a space 505 is defined between the metal diffusion preventive film 504 and the barrier metal 502 as shown in FIG. 5F.

Since the metal 503 is diffused into the wiring-to-wiring insulating film 501 through the space 505 upon execution of heat treatment in a subsequent process, a problem arises in that the insulative property of the wiring-to-wiring film 501 is reduced.

Since the surfaces of the wiring-to-wiring insulating film 501, barrier metal 502 and metal 503 are simultaneously exposed as described above after the removal of the barrier metal 502 by the CMP method, there was a possibility that the metal 503 cut by CMP would adhere onto the wiring-to-wiring insulating film 501 and the cut wiring-to-wiring insulating film 501 would be attached onto the metal 503.

Since the attached metal 503 is diffused into the wiring-to-wiring insulating film 501 even in this case, a problem arises in that the insulative property of the wiring-to-wiring insulating film 501 is degraded. Further, since the attached wiring-to-wiring insulating film 501 is diffused into the metal 501, a problem also arises in that the resistance of the metal wire increases.

Further, a problem arises in that since the metal 503 is partially eluted at the boundary between the barrier metal 502 and the metal 503 depending on the type of slurry used in CMP (see FIG. 3C), a problem arises in that the resistance of the metal wire increases.

### SUMMARY OF THE INVENTION

The present invention has been conceived to solve the previously-mentioned problems and a general object of the present invention is to provide a novel and useful semiconductor device, and method of manufacturing a semiconductor device.

A more specific object of the present invention is to achieve a high insulative property between a metal wire and an insulating film provided therearound in the case of a metal-embedded wire employed in a semiconductor device.

The above object of the present invention is achieved by a following semiconductor device and a method of manufacturing the same.

The semiconductor device comprises an insulating film placed on a semiconductor substrate and in which trenches are formed. A metal wire is formed in each of the trenches, and a metal diffusion preventive film is formed on the metal wire and the insulating film. Wherein, the upper portions of sides of the metal wire contact the metal diffusion preventive film.

In the semiconductor device, since the metal and the insulating film do not make contact with each other by the metal diffusion preventive film, a high insulative property is obtained between the metal wire and an insulating film.

According to another aspect of the present invention, in a manufacturing method of a semiconductor device, a first metal diffusion preventive film is first formed on a first insulating film placed on a semiconductor substrate. Trenches are formed within the first insulating film from the surface of the first metal diffusion preventive film. A barrier metal is formed on the internal surface of the each trench and the surface of the first metal diffusion preventive film. A metal is embedded in the each trench. Unnecessary portions of the metal are removed by CMP in a first CMP step. The barrier metal formed on the first metal diffusion preventive film is removed by CMP in a second CMP step. Finally, a second metal diffusion preventive film is formed on the surfaces of the first metal diffusion preventive film and the metal which are exposed by the second CMP step.

In the method of manufacturing a semiconductor device, since the metal and the insulating film are always separated from each other by the first metal diffusion preventive film and the barrier metal, a high insulative property is obtained between the metal wire and the insulating film.

According to another aspect of the present invention, in a manufacturing method of a semiconductor device, trenches are formed through the surface of an insulating film placed on a semiconductor substrate. Thereafter, a barrier metal is formed on the internal surface of the each trench and the surface of the insulating film. A metal is embedded in the trenches. The unnecessary portions of the metal are removed by CMP in a first CMP step. The barrier metal formed on the insulating film is removed by CMP in a second CMP step. An upper layer portion of the insulating film is removed by etching. Finally, a diffusion preventive film is formed on the post-etched insulating film and the metal.

In the method of manufacturing a semiconductor device, since the metal diffusion preventive film can prevent the diffusion of the metal into the insulating film, a high insulative property is obtained between the metal wire and the insulating film.

Other objects and further features of the present invention will be apparent from the following detailed description when read in conjunction with the accompanying drawings.

### BRIEF DESCRIPTION OF THE DRAWINGS

FIG. 1 is a cross-sectional view for describing a semiconductor device according to a first embodiment of the present invention;

FIGS. 2A to 2E are cross-sectional views for describing a method of manufacturing a semiconductor device, according to a second embodiment of the present invention;

FIGS. 3A to 3E are cross-sectional views for describing a method of manufacturing a semiconductor device, according to a third embodiment of the present invention;

FIGS. 4A to 4F are cross-sectional views for describing a method of manufacturing a semiconductor device, according to a fourth embodiment of the present invention; and

FIGS. 5A to 5F are cross-sectional views for describing a conventional method of manufacturing a semiconductor device.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefor may be omitted.

A semiconductor device to which the present invention is applied will first be described in a first embodiment.

First embodiment

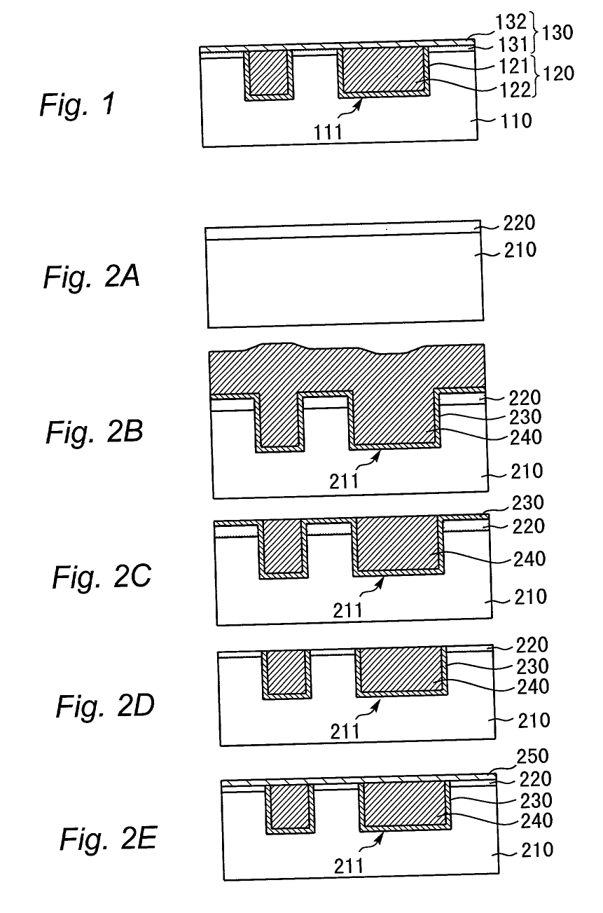

FIG. 1 is a cross-sectional view for describing a semiconductor device according to a first embodiment of the present invention.

In FIG. 1, reference numeral 110 indicates a wiring-to-wiring insulating film used as insulating film with each trench 111 formed therein. Reference numeral 120 indicates a metal wire or interconnection such as a Cu wire or interconnection, which is formed in the trench 111. Reference numeral 130 indicates a Cu diffusion preventive film used as a metal diffusion preventive film. In the drawing, the metal diffusion preventive film 130 is formed on the insulating film 110 and the metal wire 120 so as to make contact with upper portions of sides of the metal wire 120. Further, these are formed on an un-illustrated semiconductor substrate.

Now, the insulating film (wiring-to-wiring insulating film) 110 is any of an SiO₂ film or an SiO₂ film added with fluorine formed by a CVD method, an SiO₂ film formed by a plasma CVD method, and an SiO₂ film produced using a TEOS gas. Further, the trench 111 for embedding the metal wire is formed in the insulating film 110 by etching.

Further, the metal wire 120 comprises Cu 122 used as a metal member, and a barrier metal 121 formed on the bottom and both sides of the metal member 122.

In the present embodiment, Al, Au, Ag, W or an alloy of these, which has low wiring resistance, may be used as the metal member 122 other than Cu. Further, the metal member 122 is formed by the CVD method or a sputtering method. The barrier metal 121 is a thin film formed by a vapor deposition method or a sputtering method to prevent the metal member 122 from diffusing into the insulating film 110 and improve the adhesion of the metal member 122 to the trench 111. For example, the barrier metal 121 is a thin film comprised of TaN, Ti or TiN or a layered or stacked film of these.

Further, the metal diffusion preventive film 130 comprises a first metal diffusion preventive film 131 formed on the insulating 110, and a second metal diffusion preventive film 132 formed on the first metal diffusion preventive film 131 and metal wire 120. Each of these metal diffusion preventive films 130, 131 and 132 is, for example, an insulating film containing nitrogen like an SiN film (silicon nitride film) or an SiNₓO_{y} film, or an insulating film which has a low dielectric constant or a low permittivity. The insulating film has a great effect for the purpose of preventing the diffusion of the metal.

As described above, the semiconductor device according to the first embodiment includes the insulating film 110 placed on the semiconductor substrate and having the trench 111 for metal wiring, the metal wire 120 formed in the trench 111, and the metal diffusion preventive film 130 formed on the insulating film 110 and the metal wire 120 so as to contact the upper portions of the sides of the metal wire 120.

Further, the metal diffusion preventive film 130 is a layered or stacked film of the first metal diffusion preventive film 131 and the second metal diffusion preventive film 132. The upper portions of the sides of the metal wire 120 make contact with the first metal diffusion preventive film 131 formed on the insulating film 110.

The metal wire 120 includes the metal member 122 and the barrier metal formed on the bottom and both sides of the metal member 122. Upper portions of the barrier metal 121 on the sides of the metal member 122 make contact with the first metal diffusion preventive film 131.

Namely, the semiconductor device has a structure in which the metal member 122 and the insulating film 110 do not make contact with each other by the first metal diffusion preventive film 131.

Thus, even when the upper portions of the barrier metal 121 drop or sink down as compared with the surfaces of the insulating film 110 and the metal member 122, the first metal diffusion preventive film 131 can prevent the diffusion of the metal member 122 into the insulating film 110. Therefore, a high insulative property can be obtained between the insulating film 110 and the metal member 122, and the reliability of a metal-embedded wire is improved.

Owing to the use of the insulating film containing nitrogen like the silicon nitride film as the first metal diffusion preventive film 131, a high insulation effect can be obtained as compared with the use of an insulating film containing oxygen.

Methods of manufacturing semiconductor devices, to which the present invention is applied, will next be explained in second through fourth embodiments.

Second embodiment p FIGS. 2A to 2E are cross-sectional views for describing a method of manufacturing a semiconductor device, according to a second embodiment of the present invention.

As shown in FIG. 2A, a wiring-to-wiring insulating film 210 used as an insulating film composed of an SiO₂ film, for example, is first formed on an un-illustrated semiconductor substrate by a CVD method.

Further, a first metal diffusion preventive film 220 composed of an SiN film, for example, is formed on the insulating film 210 by the CVD method.

Although not shown, a resist pattern for forming each of trenches for metal embedding (hereinafter abbreviated as “trenches (or trench)”) 211 is next formed on the surface of the first metal diffusion preventive film 220. Thereafter, the trench 211 is formed in the insulating film 210 by etching with the resist pattern as a mask. After the completion of the etching, the resist pattern is removed by ashing and chemical cleaning (wet cleaning).

Further, a barrier metal 230 composed of TaN, for example, is formed on the internal surface (bottom and both sides) of each trench 211 and the surface of the first metal diffusion preventive film 220 by a vapor deposition method or a sputtering method. Thereafter, an electrolytic plating (not shown) is formed on the surface of the barrier metal 230 formed on the internal surface of the trench 211. Further a metal 240 composed of, for example, Cu is embedded into the trench 211 by the CVD method as shown in FIG. 2B.

As shown in FIG. 2C, each portion unnecessary as a wire or interconnection, of the embedded metal 240, is removed by a CMP method (hereinafter called “first CMP step”).

As shown in FIG. 2D, the barrier metal 230 formed on the first metal diffusion preventive film 220 is further removed by the CMP method (hereinafter called “second CMP step”).

Finally, a second metal diffusion preventive film 250 composed of, for example, an SiN film is formed on the surfaces of the first metal diffusion preventive film 220 and metal 240, which have been exposed after the execution of the second CMP step, by the CVD method as shown in FIG. 2E.

The semiconductor device (see FIG. 2E) manufactured through the above-described process steps has the same structure as that of the semiconductor device (see FIG. 1) described in the first embodiment. Namely, the manufacturing method according to the second embodiment is one method of manufacturing the semiconductor device according to the first embodiment.

In the method of manufacturing the semiconductor device, according to the second embodiment described above, the first metal diffusion preventive film 220 is formed on the insulating film 210 and thereafter each trench 211 for metal embedding is formed therein. The barrier metal 230 is formed on the internal surface of the trench 211 and the surface of the first metal diffusion preventive film 220, and the metal 240 is embedded in the trench 211 subsequently to the electrolytic plating process. Further, the metal 240 unnecessary for wiring is removed in the first CMP step and the barrier metal 230 is thereafter removed in the second CMP step. The second metal diffusion preventive film 250 is formed on the surfaces of the first metal diffusion preventive film 220 and the metal 240, which are exposed after the completion of the second CMP step.

According to the present manufacturing method, the metal 240 is always isolated from the insulating film 210 by the first metal diffusion preventive film 220 or the barrier metal 230. Namely, the metal 240 cut by CMP is not attached to the surface of the insulating film 210. Further, since the insulating film 210 is always covered with the first metal diffusion preventive film 220, the insulating film 210 is not cut by CMP.

Thus, since the metal 240 is not diffused into the insulating film 210, a high insulative property is obtained between the insulating film 210 and the metal 240. Further, since no insulating film 210 is diffused into the metal 240, the resistance of the metal 240 can be prevented from increasing.

Thus, since a high insulative property can be obtained between the metal wire (barrier metal 230 and metal 240) and the insulating film 210, and the resistance of the metal wire can be prevented from increasing, a metal-embedded wire or wiring is improved in reliability.

Incidentally, even an upper layer portion of the first metal diffusion preventive film 220 may be removed as well as the barrier metal 230 in the second CMP step. Thus, since the film at the boundary between the barrier metal 230 and the first metal diffusion preventive film 220 is cut away, the film quality of the exposed surface subjected to the CMP becomes uniform.

Further, the number of process steps for manufacturing the semiconductor device can be reduced by sequentially performing the first and second CMP steps.

Third embodiment

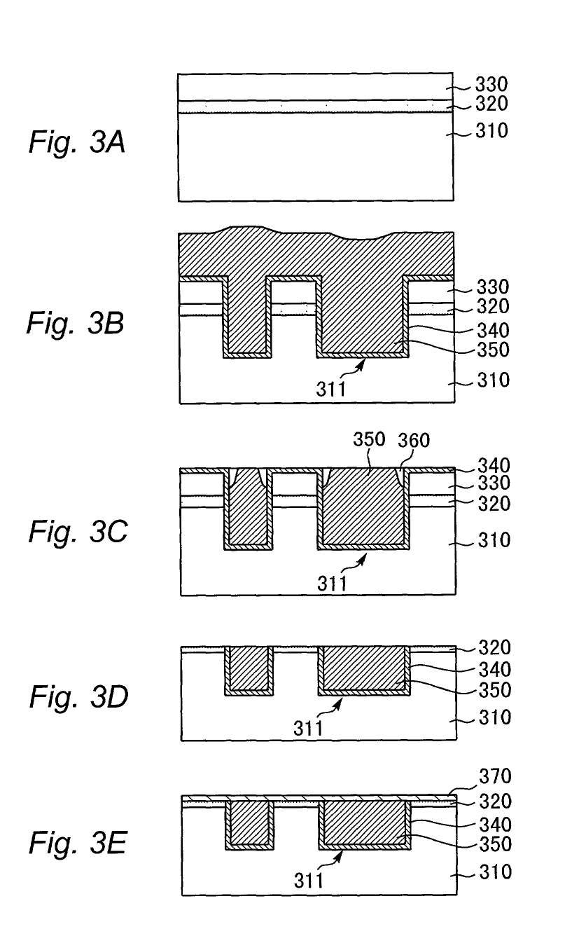

FIGS. 3A to 3E are cross-sectional views for describing a method of manufacturing a semiconductor device, according to a third embodiment of the present invention.

As shown in FIG. 3A, a wiring-to-wiring insulating film 310 used as a first insulating film composed of an SiO₂ film, for example, is first formed on an un-illustrated semiconductor substrate. Afterwards, a first metal diffusion preventive film 320 composed of an SiN film, for example, is formed on the first insulating film 310 by a CVD method.

Further, a second insulating film 330 composed an SiO₂ film, for example, is formed on the first metal diffusion preventive film 320 by the CVD method.

Next, with reference to FIG. 3B, a resist pattern (not shown) for forming each trench 311 for metal embedding (hereinafter abbreviated as “trench”) is formed on the surface of the second insulating film 330. Thereafter, the trench 311 is formed within the first insulating film 310 by etching so as to extend through the first metal diffusion preventive film 320 from the surface of the second insulating film 330 with the resist pattern as a mask. After its etching, the resist pattern is removed by ashing and chemical cleaning (wet cleaning).

Further, a barrier metal 340 composed of TaN, for example, is formed on the internal surface (bottom and both sides) of each trench 311 and the surface of the second insulating film 330 by a vapor deposition method or a sputtering method. Afterwards, an electrolytic plating (not shown) is formed on the surface of the barrier metal 340 formed on the internal surface of the trench 311. Further a metal 350 composed of Cu, for example, is embedded into the trench 311 by the CVD method.

Next, a portion of the embedded metal 350 unnecessary as each wire or interconnection is removed by a CMP method as shown in FIG. 3C (hereinafter called “first CMP step”).

Here, reference numeral 360 in the drawing indicates a space area generated by eluting some of the metal 350 by slurry used in CMP.

Next, the second insulating film 330 and the surface portion of the first metal diffusion preventive film 320 are removed by the CMP method as shown in FIG. 3D (hereinafter called “second CMP step”). The metal 350 placed in the neighborhood of the space area 360 is also removed according to the second CMP step.

Finally, a second metal diffusion preventive film 370 composed of an SiN film, for example, is formed on the surfaces of the first metal diffusion preventive film 320 and the metal 350, which are exposed after the execution of the second CMP step, by the CVD method as shown in FIG. 3E.

The semiconductor device (see FIG. 3E) manufactured through the above-described steps has the structure shown in FIG. 1, which has been described in the first embodiment.

In the method of manufacturing the semiconductor device, according to the third embodiment described above, the first metal diffusion preventive film 320 is formed on the first insulating film 310 and thereafter the second insulating film 330 is formed thereon. After the formation of each trench 311 for metal embedding, the barrier metal 340 is formed on the internal surface of the trench 311 and the surface of the second insulating film 330, and the metal 350 is embedded in the trench 311 subjected to the electrolytic plating process. The metal 350 unnecessary for wiring is removed in the first CMP step and thereafter the barrier metal 340 and the second insulating film 330 are removed in the second CMP step. Further, the second metal diffusion preventive film 370 is formed on the surfaces of the first metal diffusion preventive film 320 and the metal 350, which have been exposed after the completion of the second CMP step.

According to the present manufacturing method, even if the metal 350 placed in the neighborhood of the barrier metal 340 is eluted by slurry to thereby form the space area 360 (see FIG. 3(c)) in the first CMP step, the space area 360 does not influence a manufactured semiconductor device because it is removed in the second CMP step. Thus, the resistance value of the metal wire can be restrained from increasing, and the yield of the semiconductor device is enhanced.

In a manner similar to the manufacturing method according to the second embodiment, the metal 350 is always separated from the first insulating film 310 by the first metal diffusion preventive film 320 or the barrier metal 340 in the first and second CMP steps.

Namely, the metal 350 cut by CMP is not attached onto the surface of the first insulating film 310. Further, since the first insulating film 310 is always covered with the first metal diffusion preventive film 320, the insulating film 310 in not cut by CMP.

Thus, since the metal 350 and the insulating film 310 are not mutually diffused, a high insulative property is obtained between the metal wire and the insulating film provided therearound, and the resistance of the metal wire can be prevented from increasing. As a result, a metal-embedded wire or wiring is improved in reliability.

Incidentally, even an upper layer portion of the first metal diffusion preventive film 320 may be removed as well as the second insulating film 330 in the second CMP step. Thus, since the film at the boundary between the second insulating film 330 and the first metal diffusion preventive film 320 is cut, the film quality of the surface exposed after the second CMP step becomes uniform.

Further, the number of process steps for manufacturing the semiconductor device can be reduced by sequentially performing the first and second CMP steps.

Fourth embodiment

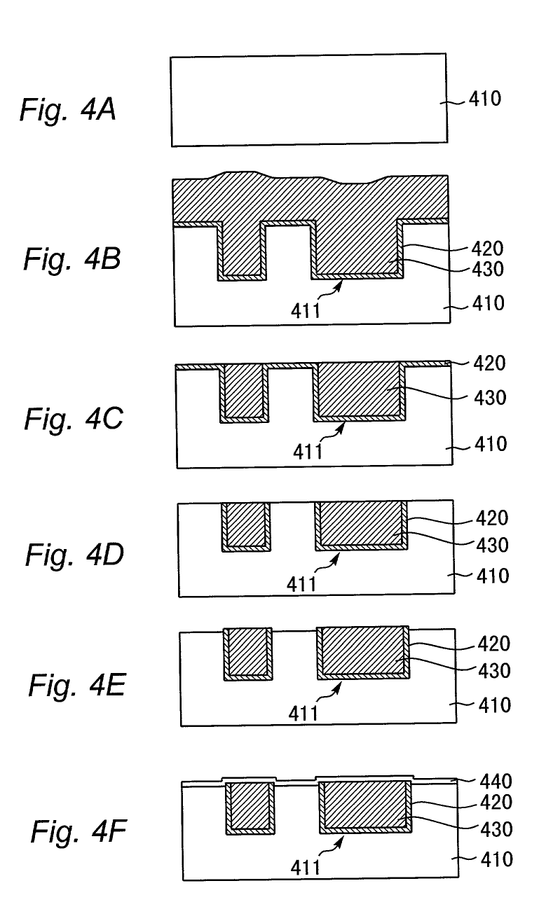

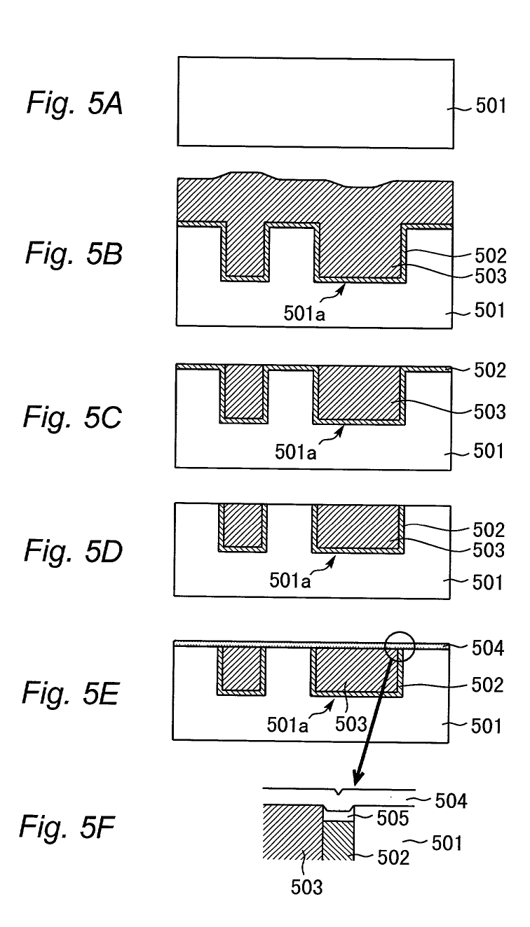

FIGS. 4A to 4F are cross-sectional views for describing a method of manufacturing a semiconductor device, according to a fourth embodiment of the present invention.

As shown in FIG. 4A, a wiring-to-wiring insulating film 410 used as an insulating film composed of a SiO₂ film, for example, is first formed on an un-illustrated semiconductor substrate by a CVD method.

Next, with reference to FIG. 4B, a resist pattern (not shown) for forming each trench 411 for metal embedding (hereinafter abbreviated as “trench”) is formed on the surface of the insulating film 410. Thereafter, the trench 411 is formed within the insulating film 410 by etching with the resist pattern as a mask. After its etching, the resist pattern is removed by ashing and chemical cleaning (wet cleaning).

Further, a barrier metal 420 composed of TaN, for example, is formed on the internal surface (bottom and both sides) of each trench 411 and the surface of the insulating film 410 by a vapor deposition method or a sputtering method. Afterwards, an electrolytic plating (not shown) is formed on the surface of the barrier metal 420 formed on the internal surface of the trench 411. Further a metal 430 composed of Cu, for example, is embedded in the trench 411 by the CVD method.

Next, a portion of the embedded metal 430 unnecessary as each wire or interconnection is removed by a CMP method as shown in FIG. 4C (hereinafter called “first CMP step”).

Further, the barrier metal 420 formed on the surface of the insulating film 410 is removed by the CMP method as shown in FIG. 4(d) (hereinafter called “second CMP step”).

Next, an upper layer portion of the insulating film 410 is etched as shown in FIG. 4E.

Now, an etching selection ratio of the insulating film 410 to the metal 430 and barrier metal 420 is set as a large value and the insulating film 410 is selectively etched. Further, the insulating film 410 is etched until the surface of the insulating film 410 becomes lower than upper ends of the barrier metal 420 formed on the sides of the metal 430.

Finally, a metal diffusion preventive film 440 composed of an SiN film, for example, is formed on the surfaces of the post-etching insulating film 410, barrier metal 420 and metal 430 by the CVD method as shown in FIG. 4F.

The semiconductor device (see FIG. 4F) manufactured through the above process steps has substantially the same structure as that of the semiconductor device described in the first embodiment (see FIG. 1). Namely, the present semiconductor device is identical with the semiconductor device described in the first embodiment in that the metal diffusion preventive film 440 is formed on the insulating film 410 and metal 430 so that the upper portions of the barrier metal 420 make contact with the metal diffusion preventive film 440, although the metal diffusion preventive film 440 of the present semiconductor device does not have a two-layer structure.

In the method of manufacturing the semiconductor device, according to the present fourth embodiment as described above, each metal embedding trench 411 is formed in the insulating film 410. Afterwards, the barrier metal 420 is formed on the internal surface of the trench 411 and the surface of the insulating film 410, and the metal 430 is embedded in the trench 411. After the metal 430 unnecessary for wiring has been removed in the first CMP step, the barrier metal 420 is removed in the second CMP step. Further, the upper layer portion of the insulating film 410 is etched until the surface of the insulating film 410 becomes lower than the upper ends of the barrier metal 420, after which the metal diffusion preventive film 440 is formed.

According to the manufacturing method, even when the upper ends of the barrier metal 420 placed on the sides of the metal 430 drop down as compared with the surface of the insulating film 410 in the second CMP step, the metal diffusion preventive film 440 is formed since the upper layer portion of the insulating film 410 is etched after the completion of the second CMP step. It is therefore possible to reliably cover the metal 430 with the barrier metal 420 or the metal diffusion preventive film 440.

Thus, since no metal 430 is diffused into the insulating film 410, a high insulative property is obtained between the insulating film 410 and the metal 430, and hence the reliability of a metal-embedded wire is improved.

Since the manufacturing method according to the fourth embodiment provides the less number of process steps, the manufacturing cost can be restrained.

This invention, when practiced illustratively in the manner described above, provides the following major effects:

According to a first aspect of the present invention, since a metal diffusion preventive film makes contact with upper portions of sides of a metal wire, a high insulative property is obtained between the metal wire and an insulating film.

In a preferred variation of the first aspect of the present invention, since a first metal diffusion preventive film contacts the upper portions of the sides of the metal wire, a high insulative property is obtained between the metal wire and the insulating film.

In another preferred variation of the first aspect of the present invention, since the first metal diffusion preventive film makes contact with upper portions of a barrier metal placed on sides of a metal member, the sides of the metal member are covered with the first metal diffusion preventive film. It is thus possible to obtain a high insulative property between the metal member and the insulating film.

In further preferred variation of the first aspect of the present invention, since the metal diffusion preventive film is an insulating film containing nitrogen, the effect of providing isolation by the metal diffusion preventive film is improved.

According to a second aspect of the present invention, since a metal and an insulating film are always separated from each other by a first metal diffusion preventive film and a barrier metal, a high insulative property is obtained between the metal and the insulating film.

In a preferred variation of the second aspect of the present invention, since the first CMP step and the second CMP step are sequentially-executed steps, the number of process steps for manufacturing a semiconductor device can be reduced.

In another preferred variation of the second aspect of the present invention, the film quality of a surface exposed according to a second CMP step becomes uniform.

According to a third aspect of the present invention, since a metal diffusion preventive film can prevent the diffusion of a metal into an insulating film, a high insulative property is obtained between the metal and the insulating film.

In a preferred variation of the third aspect of the present invention, since the first CMP step and the second CMP step are sequentially-executed steps, the number of process steps for manufacturing a semiconductor device can be reduced.

Further, the present invention is not limited to these embodiments, but variations and modifications may be made without departing from the scope of the present invention.

The entire disclosure of Japanese Patent Application No. 2000-167030 filed on Jun. 5, 2000 including specification, claims, drawings and summary are incorporated herein by reference in its entirety.

What is claimed is:

1. A semiconductor device comprising:
a semiconductor substrate;
an insulating film placed on said semiconductor substrate and in which trenches are formed;
a metal wire formed in each of the trenches; and a metal diffusion preventive film formed on said metal wire and said insulating film;
wherein upper portions of sides of said metal wire contact said metal diffusion preventive film.

2. The semiconductor device according to claim 1, wherein said metal diffusion preventive film includes a first metal diffusion preventive film formed on said insulating film and a second metal diffusion preventive film formed on said metal wire and said first metal diffusion preventive film, and the upper portions of the sides of said metal wire make contact with said first metal diffusion preventive film.

3. The semiconductor device according to claim 2, wherein said metal wire includes a metal member and a barrier metal formed on the bottom and both sides of said metal member, and upper portions of the barrier metal formed on the sides of said metal member are brought into contact with said first metal diffusion preventive film.

4. The semiconductor device according to claim 1, wherein said metal diffusion preventive film is an insulating film containing nitrogen.

5. A method of manufacturing a semiconductor device comprising:
a step of forming a first metal diffusion preventive film on a first insulating film placed on a semiconductor substrate;
a step of forming trenches within said first insulating film from the surface of said first metal diffusion preventive film;
a step of forming a barrier metal on the internal surface of said each trench and the surface of said first metal diffusion preventive film;
a step of embedding a metal in said each trench;
a first CMP step of removing unnecessary portions of said metal by CMP;
a second CMP step of removing said barrier metal formed on said first metal diffusion preventive film by CMP; and
a step of forming a second metal diffusion preventive film on the surfaces of said first metal diffusion preventive film and said metal, which are exposed by said second CMP step.

6. The method of manufacturing a semiconductor device according to claim 5, wherein said first CMP step and said second CMP step are sequentially-executed steps.

7. The method of manufacturing a semiconductor device according to claim 5, wherein an upper layer portion of said first metal diffusion preventive film is further removed in said second CMP step.

8. The method of manufacturing a semiconductor device according to claim 5, further comprising:
a step of forming a second insulating film on said first metal diffusion preventive film;
wherein in said step of forming trenches, the trenches are formed in said first insulating film so as to extend through said first metal diffusion preventive film from the surface of said second insulating film,
in said step of forming a barrier metal, the barrier metal is formed on the internal surface of said each trench and the surface of said second insulating film,
in said second CMP step, said barrier metal formed on said second insulating film and said second insulating film are removed by CMP.

9. The method of manufacturing a semiconductor device according to claim 8, wherein said first CMP step and said second CMP step are sequentially-executed steps.

10. The method of manufacturing a semiconductor device according to claim 8, wherein an upper layer portion of said first metal diffusion preventive film is further removed in said second CMP step.

11. A method of manufacturing a semiconductor device, comprising:
a step of forming trenches through the surface of an insulating film placed on a semiconductor substrate;
a step of forming a barrier metal on the internal surface of said each trench and the surface of said insulating film;
a step of embedding a metal in said each trench;
a first CMP step of removing unnecessary portions of said metal by CMP:
a second CMP step of removing said barrier metal formed on said insulating film by CMP;
a step of etching an upper layer portion of said insulating film; and
a step of forming a diffusion preventive film on the post-etched insulating film and said metal.

12. The method of manufacturing a semiconductor device according to claim 11, wherein, in said etching step, said insulating film is etched to allow the surface thereof to be lowered than the upper ends of said barrier metal placed on the sides of said metal.

13. The method of manufacturing a semiconductor device according to claim 11, wherein said first CMP step and said second CMP step are sequentially-executed steps.
